(19) United States
(12) Patent Application Publication
(10) Pub. No.: US 2026/0231472 A1
(43) Pub. Date: Aug. 6, 2026

(54) DUAL GATE THIN FILM TRANSISTOR

(71) Applicant: Taiwan Semiconductor Manufacturing Company, Ltd., Hsinchu (TW)

(72) Inventors: Yun-Feng Kao, New Taipei City (TW); Ming-Yen Chuang, Hsinchu City (TW); Katherine H. Chiang, New Taipei City (TW)

(21) Appl. No.: 19/045,597

(22) Filed: Feb. 5, 2025

(51) Int. Cl. H10D 30/67; H10D 30/01

(52) U.S. Cl. CPC H10D 30/6734; H10D 30/0312; H10D 30/6755

(57) ABSTRACT

A dual-gate thin film transistor with source, drain, and top gate structures that may be fabricated simultaneously. Each structure includes a conductive semiconductor layer, a gate dielectric layer, and a conductive core. The source and drain structures are made to function as sources and drains by positioning vias to directly contact the conductive semiconductor layer. The top gate structures are made to function as top gate electrodes by positioning vias to contact the conductive cores while avoiding contact with the conductive semiconductor layers. Differences in via width, differences between the widths of the source/drain structures and the width of the top gate structure, or differences in via alignment may be used to achieve conductive semiconductor layer contact for the source/drain structures while avoiding semiconductor layer contact for the top gate structures.

### BACKGROUND

Integrated circuit (IC) devices can contain millions or even billions of transistors. These transistors may amplify power or function as switches to enable logical operations. IC devices also typically include many passive devices like capacitors, resistors, inductors, varactors, and others. These passive components are crucial for controlling various characteristics of the IC device, such as gain, time constants, and more. Both active and passive devices are commonly used to implement memory in large-scale arrays.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one another to facilitate illustration or provide emphasis.

FIGS. 1-6 illustrate cross-sectional views of IC devices with dual-gate thin film transistors (TFTs) according to various embodiments of the present disclosure.

FIGS. 7-19 illustrate cross-sectional views of an IC device including a dual-gate TFT undergoing manufacturing in accordance with some embodiments of the present disclosure.

FIG. 20 provides a flow chart for an embodiment of a method of forming an IC device including a dual-gate TFT in accordance with the present disclosure

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

Front-end-of-line (FEOL) transistors often pose a bottleneck in the development of high-density non-volatile memories. High-density random-access memory typically requires write currents exceeding 200 μA/μm. To meet such high current demands, larger transistors or multiple transistors operating in parallel may be specified. For example, some designs employ two or more transistors per memory cell to provide sufficient drive current. These approaches result in a significant FEOL area penalty, which limits the potential for increased memory density.

Back-end-of-line (BEOL) transistors, often implemented as thin-film transistors (TFTs), offer an alternative approach. These devices typically feature an oxide semiconductor channel layer. A bottom gate electrode is typically positioned beneath the channel layer and is separated from the channel by a gate dielectric layer. Source and drain electrodes make contact with the upper surface of the channel layer. The source electrode can be electrically connected to the bottom electrode of a memory cell positioned above the TFT to provide access control.

TFT performance can be significantly enhanced by incorporating a second gate above the channel. This dual-gate configuration, with gates located both above and below the channel, improves electrostatic control, enabling precise threshold voltage tuning, reduced leakage currents, mitigation of short-channel effects, increased current density, and a steeper subthreshold slope. Dual gates can operate in unison for performance optimization or independently for additional functionality. However, the added gate structure increases fabrication complexity and cost.

The present disclosure provides a dual-gate TFT that reduces fabrication complexity and cost by eliminating a mask from the manufacturing process. Mask elimination significantly lowers costs by reducing design, production, and maintenance associated with mask usage. It also minimizes the materials, labor, and equipment required for photolithography and subsequent processing steps, thereby improving efficiency and reducing the environmental impact of manufacturing.

In the disclosed dual-gate TFT, the source, drain, and top gate structures are fabricated simultaneously, streamlining the manufacturing process. These structures include a conductive semiconductor layer, a gate dielectric layer, and a conductive core. Source and drain contact vias directly connect to the conductive semiconductor layer, enabling current to bypass the gate dielectric. In contrast, the top gate via contacts only the conductive core, avoiding contact with the conductive semiconductor layer. This via configuration allows the source and drain structures to act as simple electrical contacts, while the top gate structure provides effective channel control.

In some embodiments, the source and drain contact vias are wider than the top gate via. Wider source and drain contact vias facilitate making direct contact with the conductive semiconductor layer, while a narrower top gate via facilitates making contact with the conductive core without touching the conductive semiconductor layer.

In some embodiments, the top gate structure is wider than the source and drain structures. A wider top gate structure is another approach to facilitating making contact with the conductive core while avoiding unintended contact with the conductive semiconductor layer. Likewise, the narrower source and drain structures may facilitate contact with the conductive semiconductor layer.

In some embodiments, the top gate via is centered over the top gate structure whereas the source and drain contact vias are partially offset from being centered over the source and drain structures. The difference in alignment is another approach to facilitate making the source and drain contact vias land on the conductive semiconductor layer while the top gate via avoids the conductive semiconductor layer. The offset alignment may also be used to enable a wider spacing between the source and drain contact vias, which enables the dual-gate TFT to be made smaller without placing wires too close together

In some embodiments, the top gate via is shorter than the source and drain contact vias and connects to wire that is at a lower elevation than the wires that connect to the source and drain contact vias. Placing the wire for the top gate at a lower elevation than the wires for the source and drain also facilitates making the dual-gate TFT smaller without placing wires too close together. Shortening the top gate via also has the advantage of allowing it to be made narrower without increasing aspect ratio.

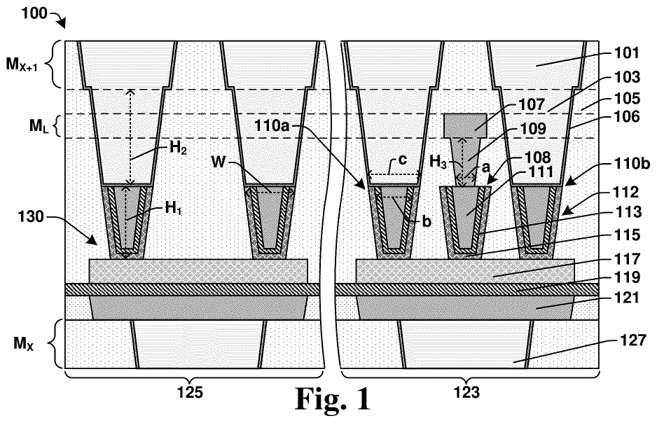

FIG. 1 illustrates a cross-sectional view of an IC device 100, highlighting the structure between metallization layers Mx and Mx+1, which are part of a metal interconnect structure positioned over a semiconductor substrate (not shown). A single-gate thin-film transistor (TFT) 130 is located in an area 125, while a dual-gate TFT 112 according to the present disclosure is positioned in an area 123.

The dual-gate TFT 112 features a channel 117, which is electrically modulated by two gate electrodes. A bottom gate electrode 121 is located beneath the channel 117 and is separated from it by a first gate dielectric layer 119. Positioned above the channel 117 is a top gate structure 108, which is flanked by a pair of source and drain structures 110a and 110b. The top gate structure 108 and the source/drain structures 110a-b are disposed over the channel 117. Each of the top gate structure 108 and the source/drain structures 110a-b comprises a conductive semiconductor layer 115, a second gate dielectric layer 113, and a conductive core 111.

Source and drain contact vias 103 are electrically coupled to the conductive semiconductor layers 115 of the source/drain structures 110a-b. Together with the conductive semiconductor layers 115, these contact vias serve as source and drain electrodes for either the dual-gate TFT 112 or the single-gate TFT 130. The source and drain contact vias 103 establish electrical contact by landing on the source/drain structures 110a-b. In some embodiments, the width c of the bases of the source and drain contact vias 103 is greater than the width b of the second gate dielectric layers 113 within the source/drain structures 110a-b. This configuration ensures reliable electrical contact between the source and drain contact vias 103 and the conductive semiconductor layers 115, provided the vias are nearly aligned with the source/drain structures 110a-b.

A top gate via 109 is electrically coupled to the conductive core 111 of the top gate structure 108 and is electrically isolated from the conductive semiconductor layer 115. The conductive core 111 functions as the top gate electrode for the dual-gate TFT 112. The top gate via 109 lands on the top gate structure 108 but is offset from the conductive semiconductor layer 115. In some embodiments, the width a of the base of the top gate via 109 is narrower than the width b of the second gate dielectric layer 113 within the top gate structure 108. This configuration enables electrical contact between the top gate via 109 and the conductive core 111 while avoiding contact with the conductive semiconductor layer 115, provided the contact via is properly aligned with the top gate structure 108.

The source/drain structures 110a-b and the top gate structure 108 have the same height, H₁, and coplanar upper surfaces. However, the source and drain contact vias 103 have a height H₂ that is greater than the height H₃ of the top gate via 109. The source and drain contact vias 103 extend upward to the metallization layer M_{X+1}, where they connect to wires 101 within that layer. In contrast, the top gate via 109 extends only far enough to connect with a wire 107 in a local metal interconnect layer M_{L}, which is positioned below the metallization layer M_{X+1}. This configuration allows the wires 101 in the metallization layer M_{X+1} to be positioned closer together, thereby facilitating a reduction in the overall size of the dual-gate TFT 112.

The local metal interconnect layer M_{L} may be distinct from the metallization layer M_{X} and M_{X+1} in terms composition, wire thickness, wire width, or wire cross-sectional area. In some embodiments, the wire 107 (of the local metal interconnect layer M_{L}) has a distinct composition from the wires 101 and 127 (of the metal interconnect layers M_{X+1} and M_{X} respectively). In some embodiments, the wire 107 is narrower than the wires 101 and 127. In some embodiments, the wire 107 is thinner than the wires 101 and 127. In some embodiments, the wire 107 has a lower cross-sectional area than the wires 101 and 127. Any of these differences may facilitate fitting the wire 107 and the via 109 between the adjacent vias 103. Any of these differences may result in the wire 107 having lower conductivity than the wires 101 and 127. The lower conductivity may be enabled by limiting the uses of the local metal interconnect layer M_{L} so that maximum currents or connection distances can be less than maximum currents or connection distances within the metallization layer M_{X} and M_{X+1}.

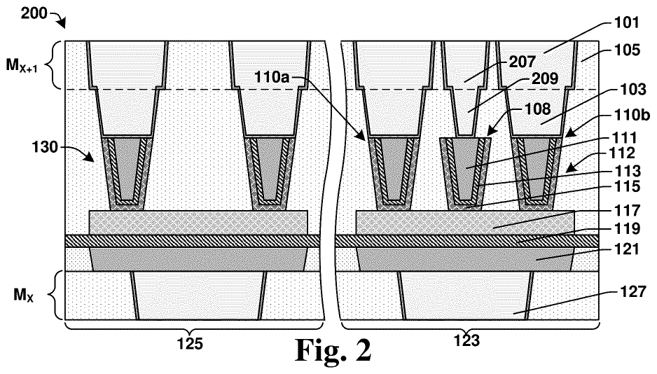

FIG. 2 illustrates a cross-sectional view of an IC device 200, which is similar to the IC device 100 of FIG. 1. In the IC device 200, the top gate structure 108 is contacted by a via 209 that has the same height and composition as the vias 103 and is connected to a wire 207 located in the metallization layer Mx+1 along with the wires 101. Although the IC device 200 is easier to manufacture than the IC device 100, the need to space the wire 207 from the wires 101 may prevent the dual-gate TFT 112 in the IC device 200 from being made as small as it can be in the IC device 100.

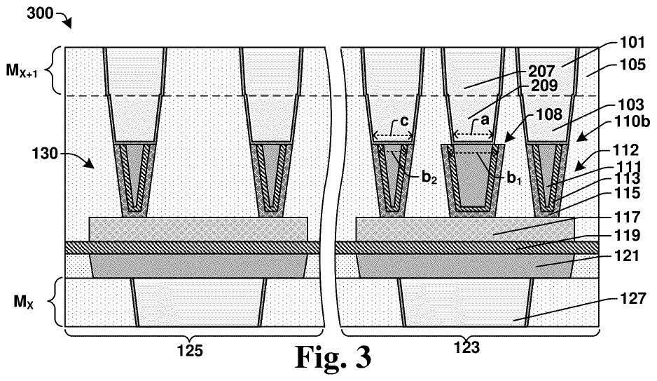

FIG. 3 illustrates a cross-sectional view of an IC device 300, which is similar to the IC device 200 of FIG. 2. In the IC device 300, the top gate structure 108 is wider than the source/drain structures 110a-b. Specifically, the width b₁ of the second gate dielectric layer 113 within the top gate structure 108 is greater than the width b₂ of the second gate dielectric layers 113 within the source/drain structures 110a-b, facilitating proper alignment. The width a of the base of the top gate via 209 may be equal to or smaller than the width c of the bases of the source and drain contact vias 103. In some embodiments, the via 209 is made narrower than the vias 103 to further facilitate proper alignment. In some embodiments, the top gate via 109 and wire 107 as shown in FIG. 1 are used in place of the top gate via 209 and wire 207 to allow the dual-gate TFT 112 to be made smaller.

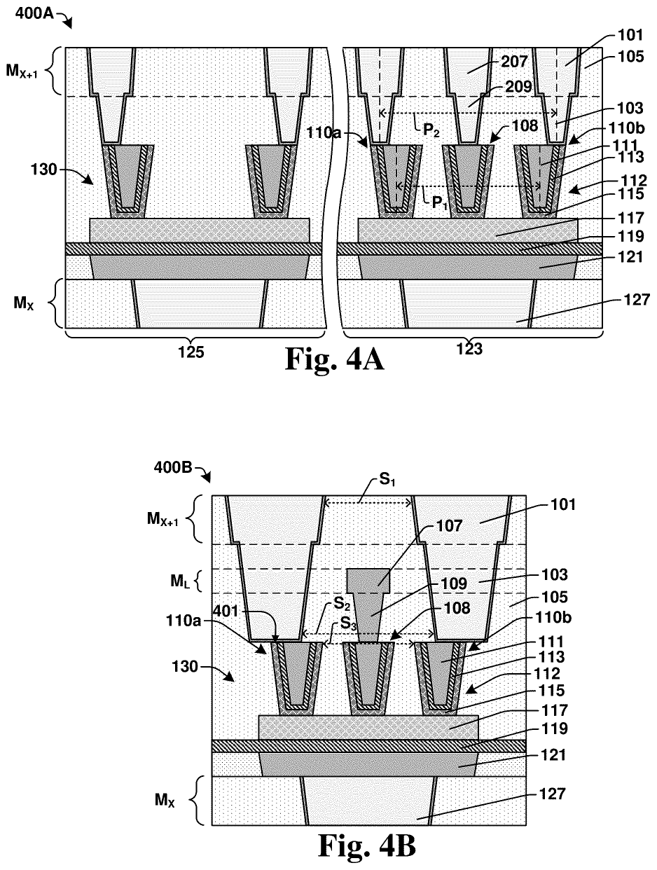

FIG. 4A illustrates a cross-sectional view of an IC device 400A, which is similar to the IC device 200 of FIG. 2. In the IC device 400A, the source and drain contact vias 103 are offset from the source/drain structures 110a-b in a way that allows the center-to-center pitch P₂ of the source and drain contact vias 103 to be greater than the center-to-center pitch P₁ of the source/drain structures 110a-b. This design facilitates maintaining a spacing between the wires 101 and the wires 207 while enabling the dual-gate TFT 112 to be made smaller.

FIG. 4B illustrates a cross-sectional view of an IC device 400B, which may be similar to the IC device 400A of FIG. 4A. The IC device 400B utilizes the local metal interconnect structure ML, allowing the top gate structure 108 to be coupled to the wire 107 while the wires 101 for the source/drain structures 110a-b are positioned adjacent to each other at a higher elevation such as within the metallization layer Mx+1. This design facilitates further reducing the size of the dual-gate TFT 112 while maintaining a spacing S₁ between the wires 101.

In some embodiments, the distance S₂ between the vias 103 (as measured at their bases 401) is greater than if they were centered over the respective source drain structures 110a-b. This configuration leave more room for the via 109 and the wire 107. In some embodiments, the spacing S₂ between the bases 401 of the vias 103 is greater than the spacing S₃ between the source drain structures 110a-b. In some embodiments, the bases 401 of the vias 103 are partially of the source drain structures 110a-b.

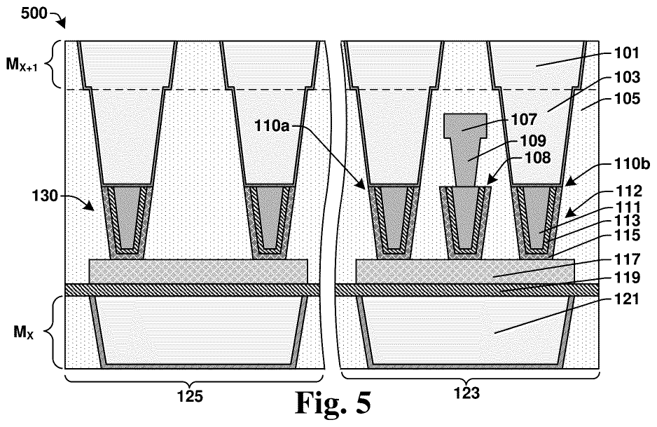

In the IC devices 100-400B of FIGS. 1 to 4B, the bottom gate electrode 121 is disposed on a wire 127 in the metallization layer M_{X}. FIG. 5 illustrates a cross-sectional view of an IC device 500, which may be similar to the IC device 100 of FIG. 1, except that the bottom gate electrode 121 is disposed within the metallization layer M_{X}. This configuration allows the bottom gate electrode 121 to be formed simultaneously with the metallization layer M_{X}, although it may constrain the choice of materials for the bottom gate electrode 121.

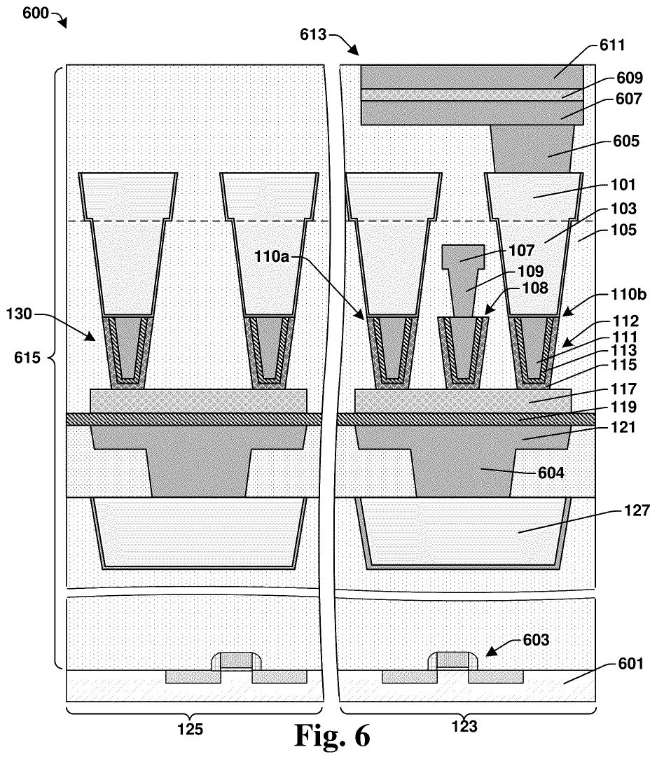

FIG. 6 illustrates a cross-sectional view of an IC device 600, which may also be similar to the IC device 100 of FIG. 1, except that the bottom gate electrode 121 is connected to the metallization layer M_{X} by a via 604. The via 604 allows the dual-gate TFT 112 to be positioned closer to the metallization layer M_{X+1}, which in turn reduces the heights of the vias 103. Reducing the heights of the vias 103 enables them to be narrower while maintaining aspect ratio. Another advantage of reducing the heights of the vias 103 is that it facilitates aligning the vias 103 with respect to the source/drain structures 110a-b.

FIG. 6 shows more details compared to FIGS. 1-5. As illustrated in FIG. 6, the IC device 600 includes a semiconductor substrate 601 and a metal interconnect structure 615. Transistors 603, along with other front-end-of-line (FEOL) devices, may be formed on or within the semiconductor substrate 601. The single-gate TFT 130 and the dual-gate TFT 112 are positioned within the metal interconnect structure 615. A memory cell 613 may be located above the dual-gate TFT 112, also within the metal interconnect structure 615. The memory cell 613 includes a data storage structure 609 positioned between a top electrode 611 and a bottom electrode 607. The bottom electrode 607 may be electrically coupled to one of the wires 101 through a via 605 so that the dual-gate TFT 112 provides an access control device for the memory cell 613.

The semiconductor substrate 601 may be a bulk semiconductor substrate, a semiconductor on insulator (SOI) substrate, or any other type of substrate. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor. FEOL devices formed on or in the semiconductor substrate 601 may include transistors, diodes, capacitors, memory cells, thyristors, resistors, the like, or any combination thereof.

The metal interconnect structure 615 includes a plurality of metallization layers separated by via layers. Each metallization layer comprising conductive traces such as the wires 101 and 127 surrounded by inter-layer dielectric 105. Etch stop layers (not show) may be disposed over the metallization layers. Each via layer comprising conductive vias such as the vias 103 that may interconnect the conductive traces and are surrounded by the inter-layer dielectric 105. The conductive traces and the conductive vias are electrically coupled in a predefined manner and configured to provide electrical connections between various devices disposed throughout the IC device 600.

The inter-layer dielectric 105 may include layers of silicon dioxide (SiO₂), low-k dielectric, extremely low-k dielectric, or other dielectrics. A low-k dielectric is one having a smaller dielectric constant than silicon dioxide (SiO₂). SiO₂ has a dielectric constant of about 3.9. Examples of low-k dielectrics include organosilicate glasses (OSG) such as carbon-doped silicon dioxide, fluorine-doped silicon dioxide (otherwise referred to as fluorinated silica glass (FSG), organic polymer low-k dielectrics, and porous silicate glass. An extremely low-k dielectric is a material having a dielectric constant of about 2.1 or less. An extremely low-k dielectric material is generally a low-k dielectric material formed into a porous structure. Porosity reduces the effective dielectric constant. In some embodiments, the inter-layer dielectric 105 is or comprises a low-k or extremely low-k dielectric.

The memory cell 613 may be a capacitor, a resistive random access memory (ReRAM), magnetoresistive random access memory (MRAM), ferroelectric random access memory (FeRAM), phase-change memory (PCM), oxygen displacement memory (OxRAM), conductive bridging random access memory (CBRAM), carbon nanotube random access memory (NRAM), the like, or any other type of memory.

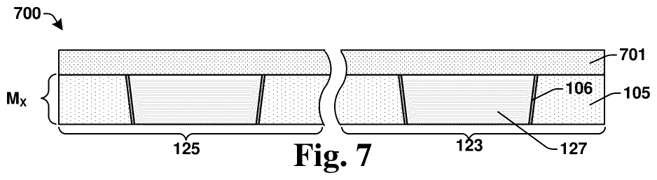

FIGS. 7-19 provide a series of cross-sectional views 700-1900 that illustrate an IC device according to the present disclosure at various stages of manufacture according to a process of the present disclosure. Although FIGS. 7-19 are described in relation to a series of acts, it will be appreciated that the order of the acts may be altered in some cases and that this series of acts are applicable to structures other than the ones illustrated. In some embodiments, some of these acts may be omitted in whole or in part. Furthermore, FIGS. 7-19 are described in relation to a series of acts, it will be appreciated that the structures shown in FIGS. 7-19 are not limited to a method of manufacture but rather may stand alone as structures separate from the method.

As shown by the cross-sectional view 700 of FIG. 7, the process may begin with forming a first inter-layer dielectric layer 701 over the metallization layer Mx. The first inter-layer dielectric layer 701 may be the same as the inter-layer dielectric 105 or may be one or more layers of other dielectrics such as silicon dioxide (SiO₂), aluminum oxide (AlOx), silicon nitride (SiN), silicon carbide (SiC), silicon carbonitride (SiCN), silicon oxycarbide (SIOC), silicon oxycarbonitiride (SiOCN), combinations thereof, or the like. These layers may be formed by chemical vapor deposition (CVD), physical vapor deposition (PVD), atomic layer deposition (ALD), the like, or any other suitable processes.

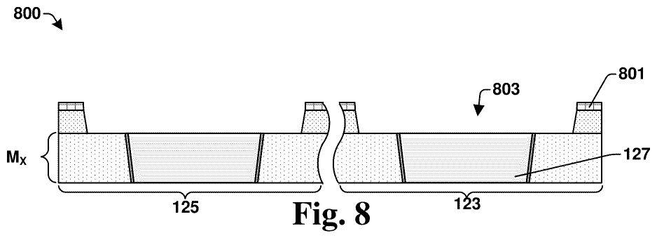

As illustrated in the cross-sectional view 800 of FIG. 8, a mask 801 may be formed and used to etch holes 803 through which the wires 127 are exposed. The mask 801 and other masks used in processes of this disclosure may be or comprise a photoresist, a hard mask, or the like. The mask 801 and other masks used in processes of this disclosure may be patterned by photolithography, ion beam lithography, the like, or some other suitable process. The etch process may be a dry etch such as a plasma etch, the like, or some other suitable process. After the etch process, the mask 801 may be stripped.

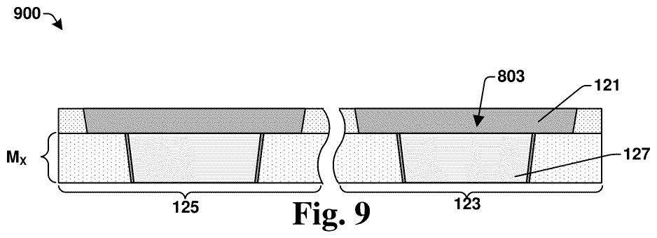

As illustrated in the cross-sectional view 900 of FIG. 9, the holes 803 are filled with conductive material to form bottom gate electrodes 121. The conductive material may be deposited by CVD, PVD, ALD, electroplating, electroless plating, the like, or any other suitable process. Excess material may be removed by a planarization process such as chemical mechanical polishing (CMP) or the like. The conductive material may be or comprises a metal, a conductive metal compound, or a conductive semiconductor. Examples of metals that may be used include silver (Ag), aluminum (Al), copper (Cu), tungsten (W), alloys thereof, and the like. Examples of conductive metal compounds include titanium nitride (TiN), tantalum nitride (TaN), metal silicide, combinations thereof, and the like. Examples of conductive semiconductors include polycrystalline silicon, degenerately doped silicon, and the like.

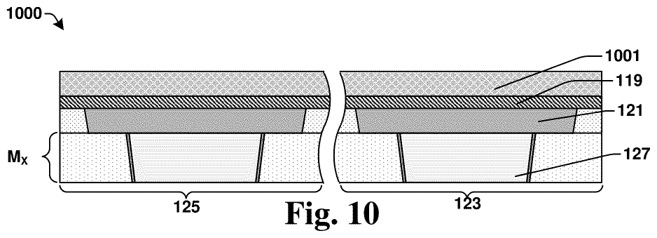

As illustrated in the cross-sectional view 1000 of FIG. 10, the first gate dielectric layer 119 and a channel layer 1001 may be deposited over the bottom gate electrodes 121. The first gate dielectric layer 119 may be or comprise silicon dioxide (SiO₂); a medium-k dielectric such as silicon nitride (SiN), silicon oxynitride (SiON), or the like; or a high-k dielectric such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium silicate (ZrSiO₄), zirconium aluminate (ZrAl₂O₅), titanium oxide (TiO₂), aluminum oxide (Al₂O₃), hafnium oxide aluminum oxide (HfO₂-Al₂O₃), alloys or combinations thereof, and the like. The thickness of the first gate dielectric layer 119 layer may be in the range from about 3 nm to about 15 nm. If the first gate dielectric layer 119 is too thin, leakage may be excessive. If the first gate dielectric layer 119 is too thick, low voltage operation may be too slow or prevented entirely. The first gate dielectric layer 119 may be formed by ALD, CVD, PVD, the like, or any other suitable process.

The channel layer 1001 may be any suitable semiconductor. In some embodiment, the channel layer 1001 is an oxide semiconductor. Oxide semiconductor have advantages such as high electron mobility and excellent uniformity. In some embodiments, the oxide semiconductor is one having the formula InₓGa_{y}Zn_{z}MO, where M is titanium (Ti), aluminum (Al), silver (Ag), tungsten (W), cerium (Ce), or tin (Sn) and x is in the range from 0 to 1, y is in the range from 0 to 1, and z is in the range from 0 to 1. Examples include indium gallium zinc oxide (IGZO), indium tungsten oxide (IWO), indium zinc oxide (IZO), indium gallium oxide (IGO), indium zinc oxide (InZnO), indium tin oxide (InSnO), gallium oxide (GaO), indium oxide (InO), aluminum zinc oxide (AlZnO), aluminum zinc tin oxide (AZTO), indium titanium oxide (InTiO), gallium zinc oxide (GZO), combinations thereof, and the like. In some embodiments, the channel layer 1001 has a thickness in the range from about 2 nm to about 15 nm. If the channel layer 1001 is too thin, its conductivity may be insufficient. If the channel layer 1001 is too thick, gate control may not be efficient.

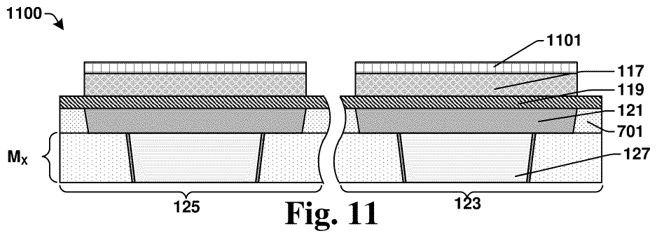

As illustrated in the cross-sectional view 1100 of FIG. 11, a mask 1101 may be formed and used to pattern the channels 117 from the channel layer 1001. The etch process may be a dry etch such as a plasma etch, the like, or any other suitable process. The etch may stop on the first gate dielectric layer 119. Alternatively, the etch may continue through the first gate dielectric layer 119 and stop on the first inter-layer dielectric layer 701 or some other layer.

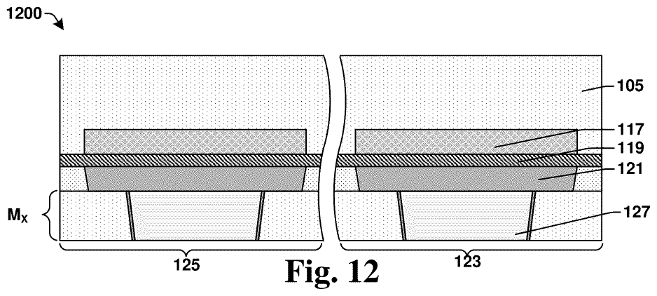

As illustrated in the cross-sectional view 1200 of FIG. 12, a layer of the inter-layer dielectric 105 may be deposited over the channel 117. The inter-layer dielectric 105 may be deposited by CVD, PCD, ALD, the like, or some other process. In some embodiments, the layer or inter-layer dielectric 105 is planarized after deposition by CMP or the like.

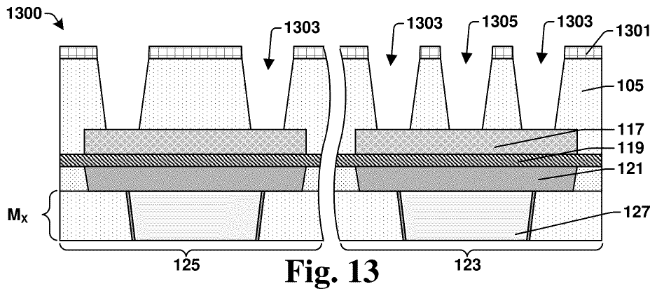

As illustrated in the cross-sectional view 1300 of FIG. 13, a mask 1301 may be formed and used to pattern holes 1303 and 1305. The holes 1303 and 1305 extend through the inter-layer dielectric 105 and are positioned over the channels 117. The etch process may be a dry etch such as a plasma etch, the like, or any other suitable process. The holes 1303 correspond to source/drain structures 110a-b (see FIG. 1), while the holes 1305 correspond to top gate structures 108. In some embodiments, the holes 1305 have the same widths as the holes 1303. In other embodiments, the holes 1305 are wider than the holes 1303.

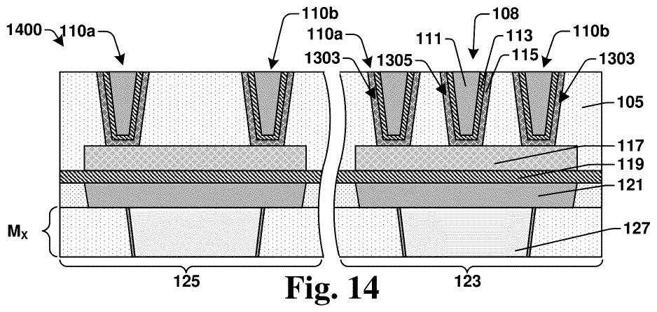

As illustrated in the cross-sectional view 1400 of FIG. 14, the conductive semiconductor layer 115, the second gate dielectric layer 113, and the conductive core 111 are deposited to fill the holes 1303 and 1305. In some embodiments, the conductive semiconductor layer 115 is an oxide semiconductor. The conductive semiconductor layer 115 has a higher specific conductance than the channel 117. The composition of the conductive semiconductor layer 115 may be the same as that of the channel 117, but with a higher dopant concentration. For example, the channel 117 may have a dopant concentration in the range from about 5×10¹⁶ atoms/cm³ to about 1×10¹⁸ atoms/cm³, while the conductive semiconductor layer 115 may have a dopant concentration in the range from about 1×10¹⁸ atoms/cm³ to about 1×10²⁰ atoms/cm³. In some embodiments, the conductive semiconductor layer 115 is degenerately doped. In some embodiments, the conductive semiconductor layer 115 has a thickness in the range from about 2 nm to about 15 nm. If the conductive semiconductor layer 115 is too thin, it may lack sufficient conductivity to enable proper operation of the source/drain structures 110a-b (see FIG. 1). Conversely, if the layer is too thick, effective top gate control may be compromised.

The composition of the second gate dielectric layer 113 may be the same as or different from that of the first gate dielectric layer 119. Likewise, its thickness may be the same or different. The second gate dielectric layer 113 may be silicon dioxide (SiO₂), a medium-k dielectric, or a high-k dielectric. In some embodiments, the second gate dielectric layer 113 is a high-k dielectric. The thickness of the second gate dielectric layer 113 layer may be in the range from about 3 nm to about 15 nm. If the second gate dielectric layer 113 is too thin, leakage may be excessive. If the second gate dielectric layer 113 is too thick, low voltage operation through the top gate may be ineffective.

The conductive core 111 may be a metal, a conductive metal compound, a conductive semiconductor, or any other suitable conductive material. The conductive material may be the same as or different from the bottom gate electrode 121. The conductive semiconductor layer 115, the second gate dielectric layer 113, and the conductive core 111 may be deposited by processes such as CVD, PVD, ALD, electroplating, electroless plating, the like, or any other suitable processes. Material that deposits outside the holes 1303 and 1305 may be removed by a planarization process such as CMP or the like. This material that remains in the holes 1303 and 1305 provides the source/drain electrode structure 110a-b and the top gate structures 108.

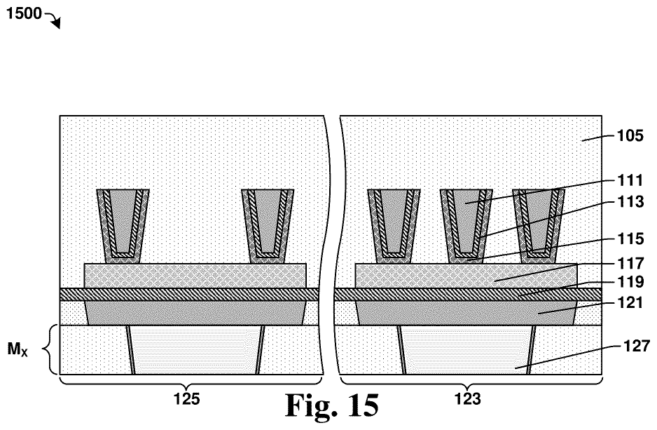

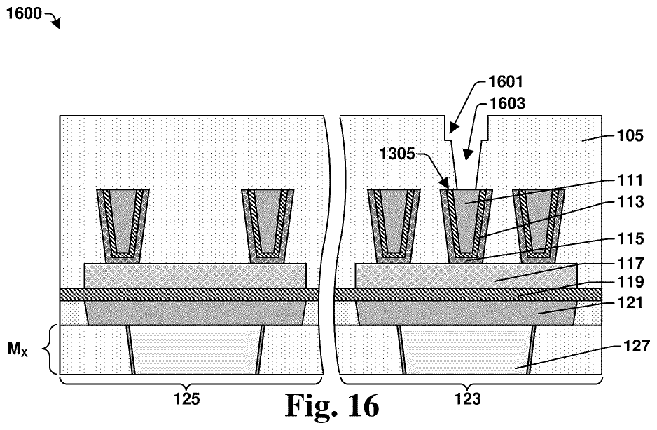

As illustrated in the cross-sectional view 1500 of FIG. 15, another layer of the inter-layer dielectric 105 may be deposited over the channel 117. As illustrated by the cross-sectional view 1600 of FIG. 16, a trench 1601 and a hole 1603 are etched into the inter-layer dielectric 105 to create an opening through which the conductive core 111 of the top gate structure 108 is exposed. The hole 1603 is positioned within the trench 1601 and is aligned with the top gate structure 108 so that the conductive core 111 is exposed without also exposing the conductive semiconductor layer 115. The trench 1601 and the hole 1603 are formed through a process of masking and etching. This process may follow either a hole-first or trench-first sequence.

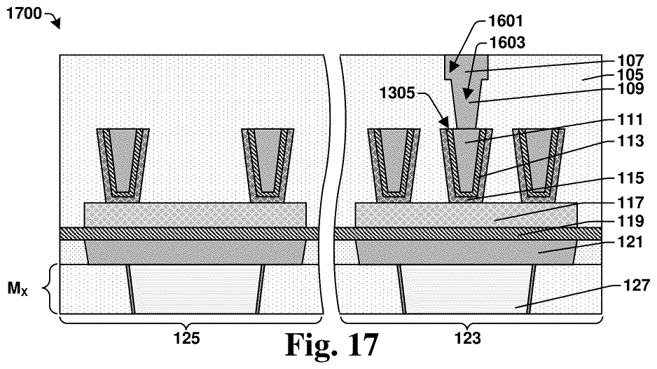

As illustrated in the cross-sectional view 1700 of FIG. 17, conductive material is deposited so as to fill the hole 1603 and the trench 1601 and create the via 109 and the wire 107. The conductive material may include one or more layers of a metal such as copper (Cu), aluminum (Al), tungsten (W), silver (Ag), tungsten (W), cerium (Ce), tin (Sn), ruthenium (Ru), palladium (Pd), platinum (Pt), cobalt (Co), nickel (Ni), zirconium (Zi), titanium (Ti), tantalum (Ta), conductive carbides, oxides, alloys of these metals, the like, or any other suitable conductive materials. In some embodiments, the conductive material includes a metal or conductive metal compound commonly used for contact plugs such as tungsten (W), cobalt (Co), cobalt silicide (CoSi₂), nickel (Ni), nickel silicide (NiSi), or the like. These materials have good conductivity and resist diffusion. In other embodiments, the conductive material includes a metal commonly used for high performance metal interconnect structures such as copper (Cu), aluminum (Al), silver (Ag), ruthenium (Ru) or the like. These later materials, especially copper (Cu), may be deposited with a diffusion barrier layer of titanium (Ti), tantalum (Ta), titanium nitride (TiN), tantalum nitride (TaN), or the like. These materials may be deposited by electroplating, electroless plating, ALD, CVD, PVD, the like, or any other suitable process. Excess material may be removed by CMP or the like.

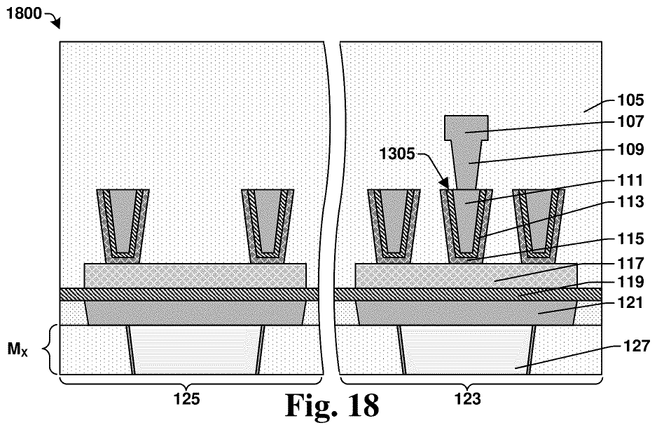

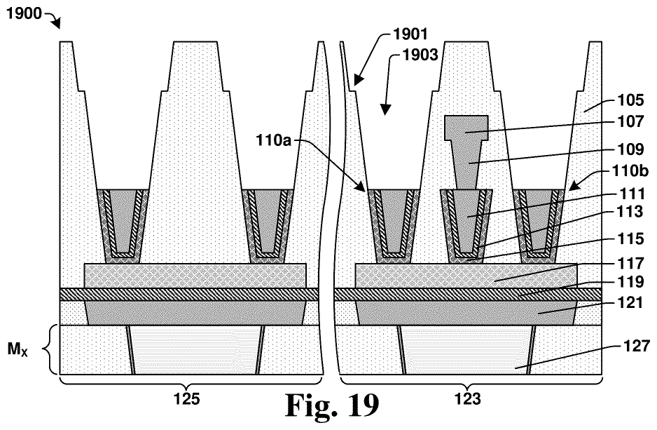

As illustrated in the cross-sectional view 1800 of FIG. 18, another layer of the inter-layer dielectric 105 may be deposited. As illustrated by the cross-sectional view 1900 of FIG. 19, trenches 1901 and holes 1903 are etched into the inter-layer dielectric 105 to create openings through which the conductive semiconductor layers 115 of the source/drain structures 110a-b are exposed. The holes 1903 may be aligned over respective source/drain structures 110a-b, or may be partially offset. The trenches 1901 and the holes 1903 are formed through a process of masking and etching with either a hole-first or trench-first sequence.

The trenches 1901 and the holes 1903 may be filled with conductive material to form the vias 103 and the wire 101 as shown in FIG. 1. The conductive material may be the same as or different from the conductive material that forms the via 109 and the wire 107. The conductive material may be deposited by electroplating, electroless plating, ALD, CVD, PVD, the like, or any other suitable process. Excess material may be removed by CMP or the like. In some embodiments, the conductive material includes the diffusion barrier layer 106. The diffusion barrier layer 106 may be titanium (Ti), tantalum (Ta), titanium nitride (TiN), tantalum nitride (TaN), the like, or any other suitable barrier material. The conductive material may be or comprise copper (Cu), aluminum (Al), silver (Ag), ruthenium (Ru), the like, or any other suitable material. In some embodiments, the conductive material comprises copper (Cu).

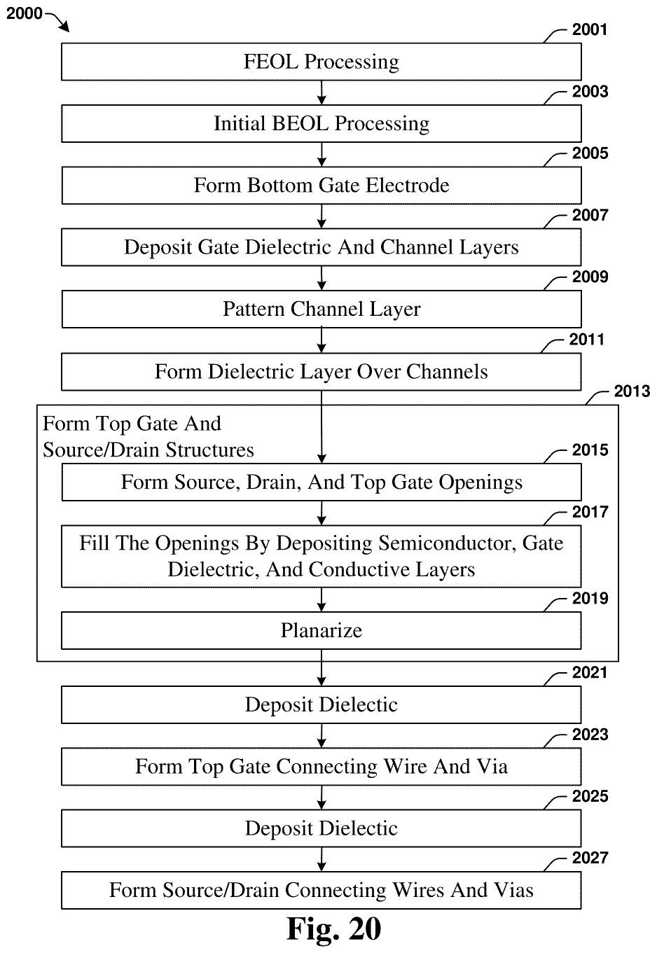

FIG. 20 provides a flow diagram for a method 2000 of forming an IC device according to some embodiments. While the method 2000 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2000 begins with act 2001, FEOL processing of a substrate. The substrate may be a semiconductor substrate. FEOL processing may form semiconductor devices such as transistors, diodes, capacitors, memory cells, thyristors, resistors, the like, or any combination thereof in or at the surface of the substrate.

Act 2003 is initial BEOL processing that may form the first few layers of a metal interconnect structure. The first few layers may include a plurality of metallization layers interleaved with via layers.

Act 2005 is forming a bottom gate electrode in or over one of the metallization layers. The bottom gate electrode may be formed directly over a wire in the metallization layer. The cross-sectional view 900 of FIG. 9 provides an example. Alternatively, the bottom gate electrode may be provided by a wire in the metallization layer or may be offset above the metallization layer and connected to the wire by a via. FIGS. 5 and 6 illustrate these alternatives.

Act 2007 is depositing gate dielectric and channel layers over the bottom gate electrode. The cross-sectional view 1000 of FIG. 10 provides an example. Act 2009 is patterning the channel layer. The cross-sectional view 1100 of FIG. 11 provides an example. Act 2011 is forming a dielectric layer over the channel. The cross-sectional view 1200 of FIG. 12 provides an example.

Act 2013 is a series of steps through which source/drain structures and top gate structures are simultaneously formed. The source drain/structures may be for dual-gate TFTs, single-gate TFTs, a combination thereof, or other devices. Single-gate TFTs may be used in the same integrated circuit device as dual-gate TFT as each type has distinct advantages. Single-gate TFTs can be more compact, whereas dual gate TFTs have superior electrostatic control.

Act 2015 is etching openings through the dielectric formed by act 2011 at desired locations for source/drain and top gate structures. In some embodiments, the openings for the top gate structures have the same width as the openings for the for source/drain structures. The cross-sectional view 1300 of FIG. 13 provides an example. In other embodiments, the openings for the top gate structures are wider than the openings for the for source/drain structures. This variation may be used to produce an IC device like the one shown in FIG. 3.

Act 2017 is depositing semiconductor, gate dielectric, and conductive layers to fill the openings. Act 2019 is planarizing. Portions of the semiconductor, gate dielectric, and conductive layers that remain within the openings after planarizing provide the source/drain and top gate structures. The cross-sectional view 1400 of FIG. 14 provides an example.

Act 2021 is forming a dielectric layer over the source/drain and top gate structures. The cross-sectional view 1500 of FIG. 15 provides an example. Act 2023 is etching a trench and a hole and filling them with conductive material to form a via that connects to the conductive core of the top gate structure and a wire that connects to the via. These wires and vias may be formed by two damascene processes or a dual damascene process. The cross-sectional views 1600 and 1700 of FIGS. 16 and 17 provide an example. The hole is narrower than the dielectric portion of the top gate structure so that the via can be positioned to contact the conductive core without contacting the semiconductor layer.

Act 2025 is forming another dielectric layer. The cross-sectional view 1800 of FIG. 18 provides an example. Act 2027 is etching trenches and holes and filling them with conductive material to form vias that connects to the semiconductor layers of the source/drain structures and wires that connect to the vias. These wires and vias be formed by two damascene processes or a dual damascene process. The cross-sectional views 1800 and 1900 of FIGS. 18 and 19 provide an example. The process may continue with the formation of additional via layers, additional metallization layers, and memory cells.

In some embodiments, the holes for connecting to the source/drain structures (formed in act 2023) are wider than the holes for connecting to the top gate structures (formed in act 2027). This difference in size facilitates the formation of the different types of connections required for these structures. In some embodiments, the holes for connecting to the top gate structures are aligned to the top gate structures whereas the holes for connecting to the source/drain structures are partially offset from being centered over the source/drain structures. This difference in alignment is another way of facilitating the formation of different types of connections.

In some embodiments, the dielectric depositions of acts 2023 and 2025 are combined into one dielectric deposition and the wire and via formations of acts 2025 and 2027 are also combined. When these acts are combined, the wires are all at the same elevation. Combining these acts reduces the number of processing steps, but placing the wires connecting to the top gate structures at a lower elevation allows the TFT to be smaller.

Some aspects of the present disclosure relate to an IC device that includes a semiconductor substrate, a metal interconnect structure disposed over the semiconductor substrate, and a dual-gate TFT within the metal interconnect structure. The dual-gate TFT has a channel comprises a first semiconductor layer, a bottom gate electrode below the channel and separated from the channel by a first gate dielectric layer and a top gate structure, a source electrode structure, and a drain electrode structure above the channel, each of which include a second semiconductor layer, a conductive core, and a second gate dielectric layer between the conductive core and the second semiconductor layer. Source and drain contact vias are electrically connected to the second semiconductor layer of the source and drain electrode structures. A top electrode via electrically connected to the conductive core of the top gate structure without electrically connecting to the second semiconductor layer.

In some embodiments, the source contact via and the drain contact via have a greater height than the top electrode via. In some embodiments, the source contact via and the drain contact via have greater widths than the top electrode via. In some embodiments, the source electrode structure and the drain electrode structure are narrower than the top gate structure. In some embodiments, the top electrode via is aligned with the conductive core of the top gate structure, and the source contact via and the drain contact via are partially offset from alignment with the source electrode structure and the drain electrode structure, respectively, such that the source contact via and the drain contact via are more widely spaced than if they were centered over the source electrode structure and the drain electrode structure respectively.

In some embodiments, the second semiconductor layer has a higher specific conductance than the first semiconductor layer. In some embodiments, the bottom gate electrode is provided by a wire in a metallization layer of the metal interconnect structure. In some embodiments, the bottom gate electrode is in direct contact with a wire in a metallization layer of the metal interconnect structure. In some embodiments, the dual-gate thin-film transistor is positioned between two adjacent metallization layers of the metal interconnect structure, and the bottom gate electrode is electrically connected to a wire in a lowermost of the two adjacent metallization layers by a via. In some embodiments, the device includes a single-gate TFT. In some embodiments, the source contact via is electrically connected to a bottom electrode of a memory cell disposed within the metal interconnect structure.

Some aspects of the present disclosure relate to an IC device that includes a semiconductor substrate, a metal interconnect structure disposed over the semiconductor substrate, and a dual-gate TFT within the metal interconnect structure. The dual-gate TFT has a channel comprises a first gate structure positioned below a semiconductor channel, and a second gate structure, a source electrode structure, and a drain electrode structure positioned above the semiconductor channel. The first gate structure includes a bottom gate electrode and a first gate dielectric layer separating the bottom gate electrode from the semiconductor channel. The second gate structure, the source electrode structure, and the drain electrode structure each include a conductive core, a second semiconductor layer, and a second gate dielectric layer disposed between the conductive core and the second semiconductor layer. Source and drain contact vias electrically connected to the second semiconductor layer of the source and drain electrode structures, respectively. A gate contact via electrically connected to the conductive core of the second gate structure.

In some embodiments, the source contact via and the drain contact via are electrically connected to wires in a metallization layer of the metal interconnect structure, and the gate contact via is electrically connected to a wire below the metallization layer.

In some embodiments, the source electrode structure, the drain electrode structure, and the second gate structure have coplanar upper surfaces that include their respective conductive cores. In some embodiments, a bottom of the source contact via is wider than the second semiconductor layer of the source electrode structure, and a bottom of the gate contact via is narrower than the second semiconductor layer of the second gate structure. In some embodiments, the second semiconductor layer is degenerately doped.

Some aspects of the present disclosure relate to a method of manufacturing an IC device, the method comprising forming a bottom gate electrode within a first dielectric layer disposed over a semiconductor substrate, forming a first gate dielectric layer and a first semiconductor layer over the bottom gate electrode, patterning the first semiconductor layer to define a channel positioned over the bottom gate electrode, wherein the first gate dielectric layer is interposed between the channel and the bottom gate electrode, forming a second inter-layer dielectric layer over the channel, patterning a first opening and two second openings through the second inter-layer dielectric layer, wherein the channel is exposed through the first opening and the two second openings, depositing a second semiconductor layer, a second gate dielectric layer, and a conductive layer to line and fill the first opening and the two second openings, planarizing the deposited layers to remove portions of the second semiconductor layer, the second gate dielectric layer, and the conductive layer outside the first opening and the two second openings, such that the second semiconductor layer, the second gate dielectric layer, and the conductive layer within the first opening form a top gate structure, and the second semiconductor layer, the second gate dielectric layer, and the conductive layer within the two second openings form source and drain structures, forming a third inter-layer dielectric layer over the top gate structure and the source and drain structures, and forming a top electrode via and source and drain contact vias through the third inter-layer dielectric layer. The top electrode via lands on the conductive layer within the top gate structure and is offset from the second semiconductor layer within the top gate structure. The source and drain contact vias land on the second semiconductor layer within the source and drain structures.

In some embodiments, forming the top electrode via and the source and drain contact vias through the third inter-layer dielectric layer comprises etching a trench and a first hole within the third inter-layer dielectric layer, wherein the first hole is located within the trench, filling the first hole and the trench to form the top electrode via and a connecting wire, depositing a fourth inter-layer dielectric layer over the connecting wire and the third inter-layer dielectric layer, etching second openings that extend through the fourth inter-layer dielectric layer and the third inter-layer dielectric layer, and filling the second openings to form the source and drain contact vias. In some embodiments, the top gate structure is wider than the source and drain structures. In some embodiments, the top electrode via has a base wider than bases of the source and drain contact vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a semiconductor substrate;
a metal interconnect structure disposed over the semiconductor substrate;
a dual-gate thin-film transistor (TFT) comprising:
a channel comprises a first semiconductor layer;
a bottom gate electrode positioned below the channel and separated from the channel by a first gate dielectric layer;
a top gate structure, a source electrode structure, and a drain electrode structure positioned above the channel, each comprising:
a second semiconductor layer;
a conductive core; and
a second gate dielectric layer disposed between the conductive core and the second semiconductor layer;
a source contact via and a drain contact via, wherein the source contact via and the drain contact via are electrically connected to the second semiconductor layer of the source electrode structure and the drain electrode structure, respectively; and
a top electrode via electrically connected to the conductive core of the top gate structure.

2. The IC device of claim 1, wherein the source contact via and the drain contact via have a greater height than the top electrode via.

3. The IC device of claim 1, wherein the source contact via and the drain contact via have greater widths than the top electrode via.

4. The IC device of claim 1, wherein the source electrode structure and the drain electrode structure are narrower than the top gate structure.

5. The IC device of claim 1, wherein:
the top electrode via is aligned with the conductive core of the top gate structure; and
the source contact via and the drain contact via are partially offset from alignment with the source electrode structure and the drain electrode structure, respectively, such that the source contact via and the drain contact via are more widely spaced than if they were centered over the source electrode structure and the drain electrode structure respectively.

6. The IC device of claim 1, wherein the second semiconductor layer has a higher specific conductance than the first semiconductor layer.

7. The IC device of claim 1, wherein the bottom gate electrode is provided by a wire in a metallization layer of the metal interconnect structure.

8. The IC device of claim 1, wherein the bottom gate electrode is in direct contact with a wire in a metallization layer of the metal interconnect structure.

9. The IC device of claim 1, wherein:
the dual-gate thin-film transistor is positioned between two adjacent metallization layers of the metal interconnect structure; and
the bottom gate electrode is electrically connected to a wire in a lowermost of the two adjacent metallization layers by a via.

10. The IC device of claim 1, further comprising a single-gate TFT.

11. The IC device of claim 1, wherein the source contact via is electrically connected to a bottom electrode of a memory cell disposed within the metal interconnect structure.

12. An integrated circuit (IC) device, comprising:
a semiconductor substrate;
a metal interconnect structure disposed over the semiconductor substrate;
a dual-gate thin-film transistor (TFT) integrated within the metal interconnect structure, the dual-gate TFT comprising:
a first gate structure positioned below a semiconductor channel, the first gate structure including a bottom gate electrode and a first gate dielectric layer separating the bottom gate electrode from the semiconductor channel;
a second gate structure positioned above the semiconductor channel, the second gate structure including a conductive core, a second semiconductor layer, and a second gate dielectric layer disposed between the conductive core and the second semiconductor layer;
a source electrode structure and a drain electrode structure positioned above the semiconductor channel, each including a second semiconductor layer and a conductive core;
a source contact via and a drain contact via, each electrically connected to the second semiconductor layer of the source electrode structure and the drain electrode structure, respectively; and
a gate contact via electrically connected to the conductive core of the second gate structure.

13. The IC device of claim 12, wherein:
the source contact via and the drain contact via are electrically connected to wires in a metallization layer of the metal interconnect structure; and
the gate contact via is electrically connected to a wire below the metallization layer.

14. The IC device of claim 12, wherein the source electrode structure, the drain electrode structure, and the second gate structure have coplanar upper surfaces that include their respective conductive cores.

15. The IC device of claim 12, wherein:
a bottom of the source contact via is wider than the second semiconductor layer of the source electrode structure; and
a bottom of the gate contact via is narrower than the second semiconductor layer of the second gate structure.

16. The IC device of claim 12, wherein the second semiconductor layer is degenerately doped.

17. A method of manufacturing an integrated circuit (IC) device, the method comprising:
forming a bottom gate electrode within a first dielectric layer disposed over a semiconductor substrate;
forming a first gate dielectric layer and a first semiconductor layer over the bottom gate electrode;
patterning the first semiconductor layer to define a channel positioned over the bottom gate electrode, wherein the first gate dielectric layer is interposed between the channel and the bottom gate electrode;
forming a second inter-layer dielectric layer over the channel;
patterning a first opening and two second openings through the second inter-layer dielectric layer, wherein the channel is exposed through the first opening and the two second openings;
depositing a second semiconductor layer, a second gate dielectric layer, and a conductive layer to line and fill the first opening and the two second openings;
planarizing the deposited layers to remove portions of the second semiconductor layer, the second gate dielectric layer, and the conductive layer outside the first opening and the two second openings, such that:
the second semiconductor layer, the second gate dielectric layer, and the conductive layer within the first opening form a top gate structure, and
the second semiconductor layer, the second gate dielectric layer, and the conductive layer within the two second openings form source and drain structures;
forming a third inter-layer dielectric layer over the top gate structure and the source and drain structures; and
forming a top electrode via and source and drain contact vias through the third inter-layer dielectric layer, wherein:
the top electrode via lands on the conductive layer within the top gate structure and is offset from the second semiconductor layer within the top gate structure, and
the source and drain contact vias land on the second semiconductor layer within the source and drain structures.

18. The method of claim 17, wherein forming the top electrode via and the source and drain contact vias through the third inter-layer dielectric layer comprises:
etching a trench and a first hole within the third inter-layer dielectric layer, wherein the first hole is located within the trench;
filling the first hole and the trench to form the top electrode via and a connecting wire;
depositing a fourth inter-layer dielectric layer over the connecting wire and the third inter-layer dielectric layer;
etching second openings that extend through the fourth inter-layer dielectric layer and the third inter-layer dielectric layer; and
filling the second openings to form the source and drain contact vias.

19. The method of claim 17, wherein the top gate structure is wider than the source and drain structures.

20. The method of claim 17, wherein the top electrode via has a base wider than bases of the source and drain contact vias.
